(19) United States
(12) Patent Application Publication
(10) Pub. No.: US 2018/0019162 A1
(43) Pub. Date: Jan. 18, 2018

(54) AMORPHOUS CARBON LAYER FOR COBALT ETCH PROTECTION IN DUAL DAMASCENE BACK END OF THE LINE INTEGRATED CIRCUIT METALLIZATION INTEGRATION

(71) Applicant: GLOBALFOUNDRIES Inc., Grand Cayman (KY)

(72) Inventors: Shafaat AHMED, Malta, NY (US); Shahrukh Akbar KHAN, Danbury, CT (US); Vishal CHHABRA, Clifton Park, NY (US)

(21) Appl. No.: 15/208,852

(22) Filed: Jul. 13, 2016

(51) Int. Cl. H01L 21/768; H01L 23/522; H01L 23/532

(52) U.S. Cl. CPC H01L 21/76834; H01L 23/53238; H01L 23/5226; H01L 21/76879; H01L 21/7681; H01L 21/76846; H01L 21/76814; H01L 21/76849

(57) ABSTRACT

A method of forming an amorphous carbon (aC) layer as a barrier layer for preventing etching of metals in a dual damascene metallization process and the resulting device are provided. Embodiments include forming an inter-layer dielectric (ILD) layer over a substrate with the first ILD having recesses for a first metallization layer. Then forming a TaN barrier layer and Co liner in the recesses, filling the recesses with a metal, forming a Co cap layer over the metal and forming a conformal aC layer over the substrate are accomplished. Furthermore, an Nblock layer, an ILD layer and a metal hard mask layer completes the stack on top to the aC layer. Subsequently, the embodiments include etching vias through this stack down to the aC layer, thereby protecting the first metallized layer.

### TECHNICAL FIELD

The present disclosure relates to the manufacture of semiconductor devices, such as integrated circuits (ICs). The present disclosure is particularly applicable to forming back-end-of-line (BEOL) and middle-of-line (MOL) metallization in the 7 nanometer (nm) technology node and beyond.

### BACKGROUND

BEOL metallization and middle-of-line MOL metallization are becoming challenging due to shrinking of the critical dimension (CD) of semiconductor devices, and process capability. Cobalt (Co) has been used as a liner (replacing tantalum (Ta)) and a capping layer (instead of a manganese (Mn) barrier) for BEOL dual damascene copper (Cu) interconnect metallization from 14 nm onward for better wettability of Cu on Co, and for lower resistance of Co over Tantalum (Ta) liner and Mn. On the other hand, BEOL Cu metallization gives higher trench/via resistance than Co for CD less than 13 nm to 15 nm. This higher resistance translates to higher wire resistance and delay in signal propagation and reduction in circuit speed. Hence, there is a need to replace the Cu metallization with Co.

Furthermore, at the MOL level metallization, the conformal chemical vapor deposition (CVD) tungsten (W) metallization process gives seams/voids at the center of the trenches/vias causing higher resistance. The center voids/seams become more severe due to shrinking of the CD in most advanced nodes, namely 7 nm and 10 nm technologies. In addition, the W seam also impacts the W grain growth due to lack of physical contact of W from both side walls. As a result, Co has replaced W metallization for MOL metallization due to its unique voids free fill capability which gives approximately 40-50% lower resistance over the W metallization. However, the integration of Co metallization has challenges, mainly during the subsequent process steps such as post deposition final reactive ion etching (RIE), wet etch process and/or hard mask removal process where Co is exposed to the etchants or chemicals resulting in Co corrosion or etch out.

For example, FIG. 2A illustrates formation of Co as a liner and a capping layer. In FIG. 2A, an inter-layer dielectric (ILD) 201 is formed over a substrate typically by CVD, and recesses are formed in the ILD 201 for a first metallization layer by RIE. Then, a TaN barrier layer 203 is formed in the recesses followed by a Co liner 205. These are conformal thin films and can be deposited by either CVD, physical vapor deposition (PVD) or atomic layer deposition (ALD) processes. Subsequently, the recesses are filled with Cu 207 by electroplating process. Then, a Co cap layer 209 is formed over the Cu 207. Next, a barrier silicon-oxy-nitride (SICN) or Nblock (©Applied Materials) layer 211, a second ILD layer 213, and a TiN hard mask 215 are consecutively formed over the Co cap layer 209 and the ILD layer 201. The hard mask 215 is then patterned, and vias 217 and recesses 219 (for a second metallization layer) are etched through the hard mask 215. Adverting to FIG. 2B, a post-etch clean causes etching of the Co liner 205 and Co cap 209. The post-etch clean process is integral to the integration flow and it ensures descuming of photoresist residue in the recessed areas.

FIG. 3A illustrates a complete Co metallization. In FIG. 3A, an ILD 301 is formed over a substrate, and recesses are formed in the ILD 301 for a first metallization layer. A TaN barrier layer 303 is followed by a Co liner 305 are formed in the recesses. A Co seed layer (not shown for illustrative convenience) is formed prior to filling the recesses with Co. Subsequently, the recesses are filled with Co 307. Then, a Co cap layer 309 is formed over the Co 307. Next, a Nblock layer 311, a second ILD 313, and a TiN hard mask 315 are consecutively formed over the Co cap layer 309 and the ILD 301. The hard mask 315 is then patterned, and vias 317 and recesses 319 (for a second metallization layer) are etched through the hard mask 315. Adverting to FIG. 3B, during the next level post final RIE wet etch process and/or hard mask removal process the Co is exposed to the etchant/chemicals which causes the Co 307 to be etched or corroded.

A need therefore exists for a methodology enabling use of Co for metallization without Co corrosion and the resulting device.

### SUMMARY

An aspect of the present disclosure is a method including forming an amorphous carbon (aC) layer over the metallization layer including Co to prevent etching or corrosion of a Co liner and Co cap during a post RIE clean.

Another aspect of the present disclosure is a device including over a metallization layer including Co and an aC layer to prevent etching or corrosion of a Co liner and Co cap during a post RIE clean.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming a first ILD over a substrate, the first ILD having recesses for a first metallization layer; forming a barrier layer and Co liner in the recesses; filling the recesses with a metal; forming a Co cap layer over the metal; forming an aC layer over the substrate; forming a Nblock layer over the aC layer; forming a second ILD over the Nblock layer; forming a hard mask over the second ILD; and etching vias through the hard mask, the second ILD, and the Nblock layer down to the aC layer.

Aspects of the present disclosure include a post-etch clean. Another aspect includes etching the aC layer by nitrogen (N₂) plus hydrogen (H₂) RIE or H₂ plasma ashing subsequent to the post-etch clean. Other aspects include the barrier layer including a tantalum nitride (TaN) layer or a titanium nitride (TiN) layer. Additional aspects include forming the TaN or TiN layer to a thickness of 10 angstroms (Å) to 40 Å and the Co liner to a thickness of 5 Å to 35 Å. Another aspect includes filling the recesses with Cu. Further aspects include forming a Co seed layer prior to filling the recesses with Co. Another aspect includes forming the Co cap layer to a thickness of 10 A to 25 Å. A further aspect includes forming the aC layer to a thickness of 20 A to 30 Å. Another aspect includes forming the Co cap layer by selective CVD or ALD. Other aspects include forming the aC layer by cyclic CVD or ALD.

Another aspect of the present disclosure is a device including: an ILD over a substrate and having recesses for a first metallization layer; a barrier layer and Co liner in the recesses; a metal filling the recesses; a Co cap layer over the metal; an aC layer over the substrate; a Nblock layer over the aC layer; a second ILD over the Nblock layer; and vias through the second ILD, Nblock layer, aC layer, and Co cap layer.

Aspects of the device include the aC layer having a thickness of 20 Å to 30 Å. Other aspects include the Co cap layer having a thickness of 10 Å to 25 Å. Another aspect includes the metal including Cu or Co. Further aspects include the barrier layer including TaN or TiN.

Another aspect of the present disclosure is a method including: forming an ILD over a substrate; forming recesses in the first ILD for a first metallization layer; forming a TaN or TiN barrier layer in the recesses by PVD and a Co liner over the barrier layer by PVD, CVD or ALD; filling the recesses with Co or Cu; forming a Co cap layer over the Co or Cu; forming an aC layer over the substrate to a thickness of 20 Å to 30 Å; forming a Nblock layer over the aC layer; forming a second ILD over the Nblock layer; forming a TiN hard mask over the second ILD; forming second recesses through the hard mask and into the second ILD and forming vias through the hard mask, the second ILD, and the Nblock layer by reactive ion etching (RIE); performing a post-RIE clean; etching the aC layer through the vias by N₂ plus H₂ reactive ion etching (RIE) or H₂ plasma ashing; and filling the vias and second recesses with a second metallization layer.

Aspects of the methods include forming the TaN or TiN barrier layer to a thickness of 10 Å to 40 Å and the Co liner to a thickness of 5 Å to 35 Å. Another aspect includes forming the Co cap layer to a thickness of 10 Å to 25 Å. Other aspects include forming the aC layer to a thickness of 20 Å to 30 Å.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1A through 1C schematically illustrate sequential steps of a method for forming an aC layer as a barrier layer to prevent etching of metals, in accordance with an exemplary embodiment;

FIGS. 2A and 2B schematically illustrate post-etch clean causing etching of a Co liner and Co cap; and

FIGS. 3A and 3B schematically illustrate Co being exposed to the etchant/chemicals during post final RIE wet etch and/or hard mask removal, causing the Co to be etched or corroded.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of corrosion and etching of attendant upon post RIE cleaning after forming a Co liner and Co cap for dual damascene Co or Cu metallization or Co trenches/vias for Co metallization. In accordance with embodiments of the present disclosure, an aC layer is formed to protect the Co from corroding or being etched out during a post-etch clean. Most of the chemicals being used as a post final RIE clean, including citric dilute hydrofluoric acid (dHF) or any hard mask removal chemicals do not attack or etch the aC layer. The aC layer can be selectively etched by N₂+H₂ RIE or by H₂ plasma treatment. A high bias N₂+H₂ gas brief/touch up RIE or H₂ plasma ashing can be utilized to ash the aC layer before the metallization.

Methodology in accordance with embodiments of the present disclosure includes forming a first ILD over a substrate, the first ILD having recesses for a first metallization layer. Then, a barrier layer and Co liner is formed in the recesses. Next, the recesses are filled with a metal. Then, a Co cap layer is formed over the metal. Subsequently, an aC layer is formed over the substrate. Then, a Nblock layer is formed over the aC layer. Next, a second ILD is formed over the Nblock layer. Then, a hard mask is formed over the second ILD. Finally, the vias are etched through the hard mask, the second ILD, and the Nblock layer down to the aC layer.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

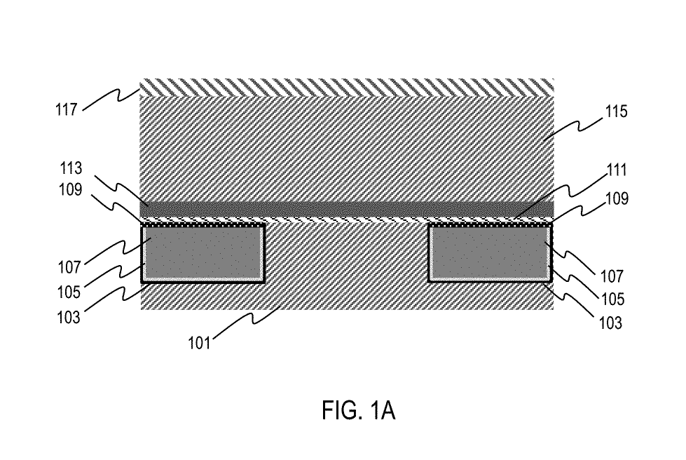

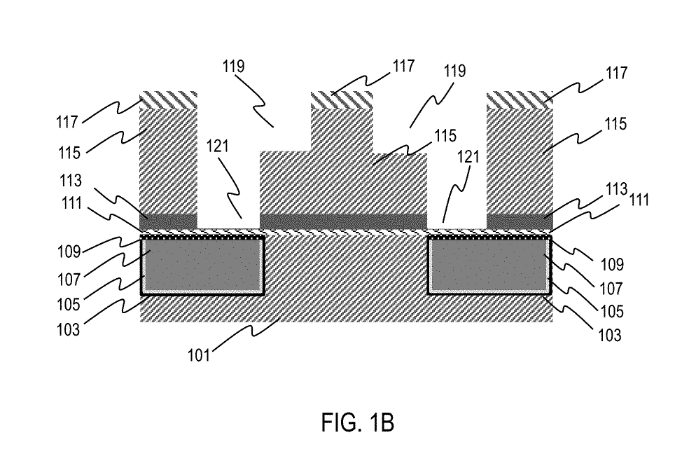

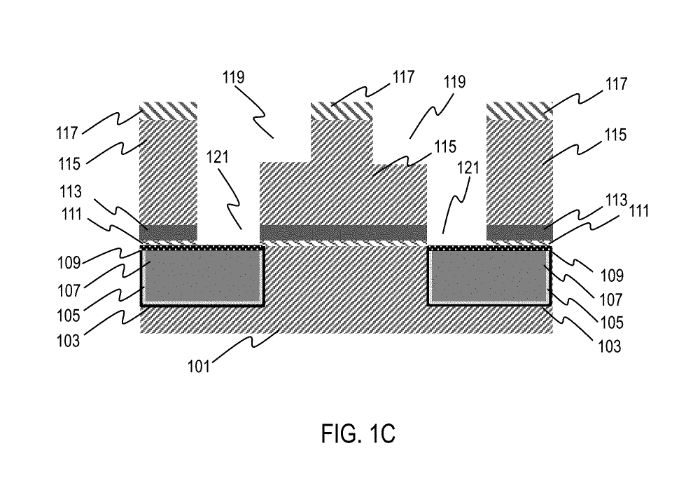

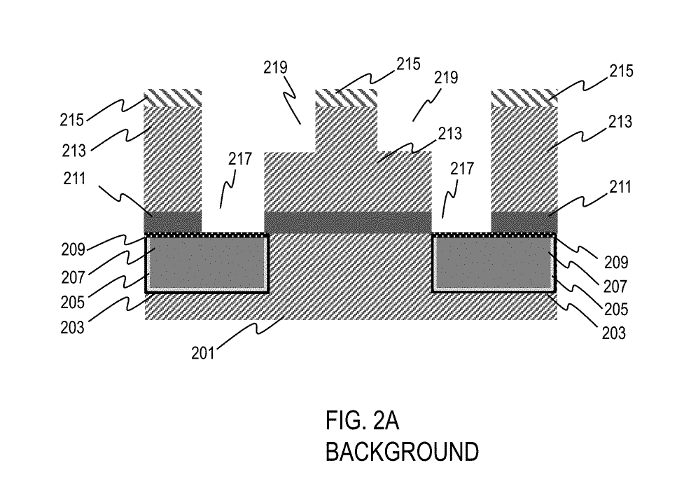

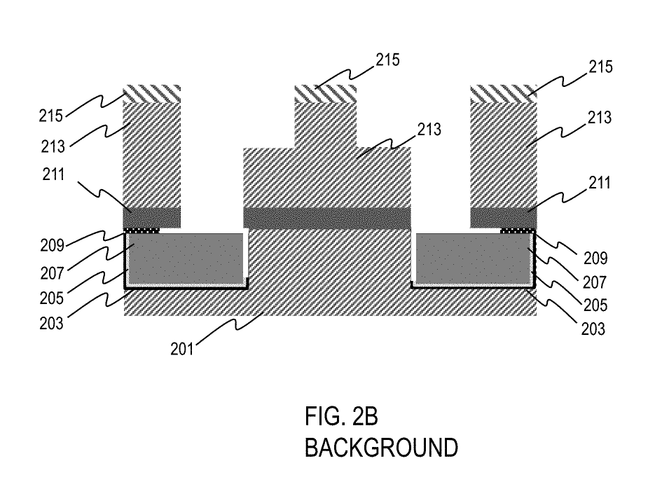

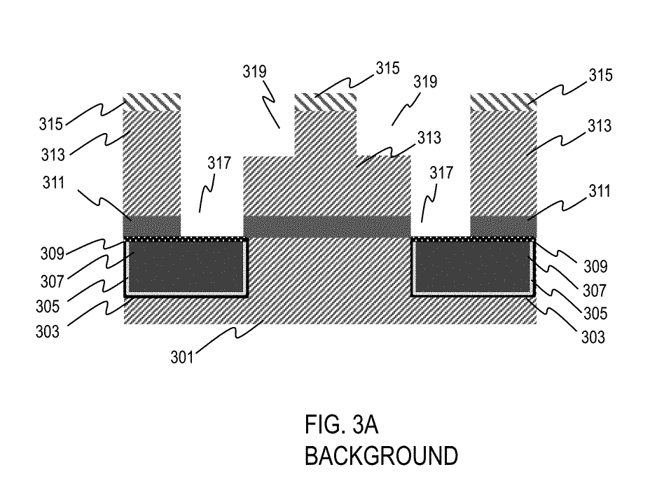

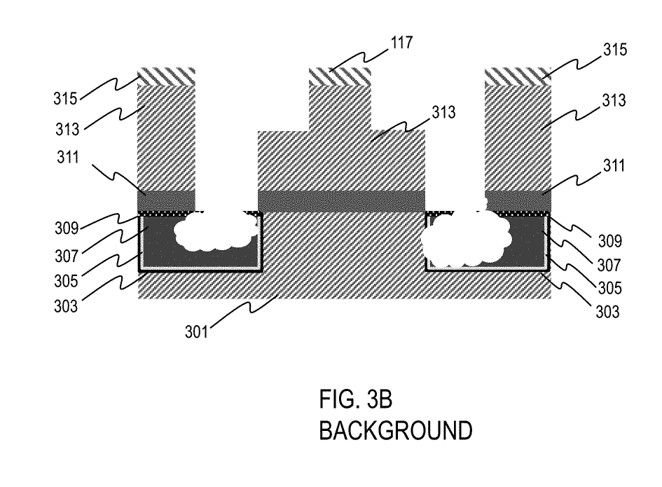

FIGS. 1A through 1C schematically illustrate sequential steps of a method of forming an aC layer as a barrier layer to prevent etching and corrosion of Co, in accordance with an exemplary embodiment. Adverting to FIG. 1A, an ILD 101 is formed over a substrate, such as a silicon wafer (not shown for illustrative convenience). Next, recesses are formed in the first ILD 101 for a first metallization layer. Then, a TaN or a TiN barrier layer 103 is formed in the recesses by PVD. The TaN or TiN barrier layer 103 is formed to a thickness of 10 Å to 40 Å. Next, a Co liner 105 is formed over the barrier layer 103 by PVD, CVD or ALD. The Co liner 105 is formed to a thickness of 5 Å to 35 Å. Subsequently, the recesses are filled with Co or Cu 107. A Co seed layer is formed prior to filling the recesses with Co. Then, a Co cap layer 109 is formed over the Co or Cu 107. The Co cap layer 109 is formed by selective CVD or ALD, for example to a thickness of 10 Å to 25 Å. Subsequently, an aC layer 111 is conformally formed over the substrate by cyclic CVD or ALD. The aC layer 111 is formed to a thickness of 20 Å to 30 Å. Then, a Nblock layer 113 is formed over the aC layer 111. The NBlock layer 113 is formed to a thickness of 100 Å to 200 Å, e.g. to a thickness of 150 Å to 200 Å. Next, a second ILD 115 is formed over the Nblock layer 113. The ILD 115 is formed to a thickness of 80 nm to 110 nm. Then, a TiN hard mask 117 is formed over the ILD 115.

Adverting to FIG. 1B, recesses 119 are formed through the hard mask 117 and into the ILD 115. Concurrently, vias 121 are formed through the hard mask 117, the ILD 115, and the Nblock layer 113 down to the aC layer 111 by RIE. Subsequently, a post-RIE clean is performed, for example with citric dHF. In FIG. 1C, the aC layer 111 is etched through the vias 121 by N₂ plus H₂ RIE or H₂ plasma ashing. Then, the vias 121 and the recesses 119 are filled with a second metallization layer and planarized by chemical mechanical polishing (CMP), removing the hard mask 117 and reducing the thickness of the ILD 115 to 65 nanometers (nm) to 90 nm.

The embodiments of the present disclosure can achieve several technical effects, such as reduced Co etching and corrosion during Co metallization and next level post final RIE wet cleaning. Devices formed in accordance with embodiments of the present disclosure enjoy utility in various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices, particularly for the 7 nm technology node and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming a first inter-layer dielectric (ILD) over a substrate, the first ILD having recesses for a first metallization layer;
forming a barrier layer and cobalt (Co) liner in the recesses;
filling the recesses with a metal;
forming a Co cap layer over the metal;
forming a conformal amorphous carbon (aC) layer directly over the first ILD and Co cap layer;
forming a Nblock layer directly over the aC layer;
forming a second ILD directly over the Nblock layer;
forming a hard mask over the second ILD; and
etching vias through the hard mask, the second ILD, and the Nblock layer down to the aC layer,
wherein the Nblock layer and the aC layer are adjacent to a bottom of the vias.

2. The method according to claim 1, further comprising:
a post-etch clean.

3. The method according to claim 2, further comprising:
etching the aC layer by nitrogen (N2) plus hydrogen (H2) reactive ion etching (RIE) or H2 plasma ashing subsequent to the post-etch clean.

4. The method according to claim 1, wherein the barrier layer comprises a tantalum nitride (TaN) layer or a titanium nitride (TiN) layer.

5. The method according to claim 4, comprising forming the TaN or TiN layer to a thickness of 10 angstroms (A) to 40 Å and the Co liner to a thickness of 5 Å to 35 Å.

6. The method according to claim 1, comprising filling the recesses with copper (Cu) layer.

7. The method according to claim 1, comprising forming a Co seed layer prior to filling the recesses with Co.

8. The method according to claim 1, comprising forming the Co cap layer to a thickness of 10 Å to 25 Å.

9. The method according to claim 1, comprising forming the aC layer to a thickness of 20 Å to 30 Å.

10. The method according to claim 1, comprising:
forming the Co cap layer by selective chemical vapor deposition (CVD) or atomic layer deposition (ALD).

11. The method according to claim 1, comprising:
forming the aC layer by cyclic CVD or ALD.

12. A device comprising:
a first inter-layer dielectric (ILD) over a substrate and having recesses for a first metallization layer;
a barrier layer and cobalt (Co) liner in the recesses;
a metal filling the recesses;
a Co cap layer over the metal;
a conformal amorphous carbon (aC) layer directly over the first ILD and Co cap layer;
a Nblock layer directly over the aC layer;
a second ILD directly over the Nblock layer; and
vias through the second ILD, Nblock layer, aC layer, and Co cap layer,
wherein the Nblock layer and the aC layer are adjacent to a bottom of the vias.

13. The device according to claim 12, wherein the aC layer has a thickness of 20 angstroms (Å) to 30 Å.

14. The device according to claim 12, wherein the Co cap layer has a thickness of 10 Å to 25 Å.

15. The device according to claim 12, wherein the metal comprises copper (Cu) or Co.

16. The device according to claim 12, wherein the barrier layer comprises tantalum nitride (TaN) or titanium nitride (TiN).

17. A method comprising:
forming a first inter-layer dielectric (ILD) over a substrate;
forming recesses in the first ILD for a first metallization layer;
forming a tantalum nitride (TaN) or titanium nitride (TiN) barrier layer in the recesses by physical vapor deposition (PVD) and a cobalt (Co) liner over the barrier layer by PVD, chemical vapor deposition (CVD) or atomic layer deposition (ALD);
filling the recesses with Co or copper (Cu);
forming a Co cap layer over the Co or Cu;
forming a conformal amorphous carbon (aC) layer directly over the first ILD and Co cap layer to a thickness of 20 Å to 30 Å;
forming a Nblock layer directly over the aC layer;
forming a second ILD over the Nblock layer;
forming a TiN hard mask over the second ILD;
forming second recesses through the hard mask and into the second ILD and forming vias through the hard mask, the second ILD, and the Nblock layer by reactive ion etching (RIE), wherein the Nblock layer and the aC layer are adjacent to a bottom of the vias;
performing a post-RIE clean;
etching the aC layer through the vias by nitrogen (N2) plus hydrogen (H2) reactive ion etching (RIE) or H2 plasma ashing; and
filling the vias and second recesses with a second metallization layer.

18. The method according to claim 17, comprising forming the TaN or TiN barrier layer to a thickness of 10 angstroms (Å) to 40 Å and the Co liner to a thickness of 5 Å to 35 Å.

19. The method according to claim 17, comprising:
forming the Co cap layer to a thickness of 10 Å to 25 Å; and
forming the aC layer to a thickness of 20 Å to 30 Å.

20. (canceled)

21. The method according to claim 17, further comprising:
planarizing the second metallization layer with chemical mechanical polishing (CMP).
